(19) United States
(12) Patent Application Publication
(10) Pub. No.: US 2010/0271044 A1
(43) Pub. Date: Oct. 28, 2010

(54) REMOTE DETECTION OF DISCHARGE ON A POWER LINE NETWORK

(75) Inventor: Jacob Keret, Kfar-Shemaryahu (IL)

Correspondence Address: MARTIN D. MOYNIHAN d/b/a PRTSI, INC., P.O. BOX 16446, ARLINGTON, VA, 22215, US

(73) Assignee: Main.Net Communications Ltd., RaAnana (IL)

(21) Appl. No.: 12/452,481

(22) PCT Filed: Mar. 13, 2008
(86) PCT No.: PCT/IL08/00351

§ 371 Date: Jul. 6, 2010

Related U.S. Application Data
(60) Provisional application No. 60/947,686, filed on Jul. 3, 2007.

(51) Int. Cl. G01R 31/02

(52) U.S. Cl. 324/544

(57) ABSTRACT

Apparatus for remote detection of discharge on a power line, including a line sampler for obtaining samples of a signal on a power line; a high pass filter for identifying high frequency components of the signal, where the high frequency components are indicative of discharge within the signal; and a reporting unit for reporting identified components as a remote discharge.

### FIELD AND BACKGROUND OF THE INVENTION

The present invention, in some embodiments thereof, relates to remote detection of discharge on a power line network and, more particularly, but not exclusively, to such remote detection by units of a communication system installed on the power line network.

Developments in power line communications, and especially in the field of smart electric grids, have started to show great promise for delivery of new and improved services to the power line infrastructure. Beyond data communications abilities that can now be provided to utilities and their customers using the power grids, it would be useful to provide additional services that may help the utilities improve their operational efficiencies.

In one example, utilities have long used insulators, to isolate a power line from a grounding wire or source, to prevent shortages in a circuit. However, it may often happen that insulators break, get dirty, loose functionality etc., in which cases current may be lost through discharge, for example, causing unwanted and even dangerous sparks. Other factors that may cause unwanted discharge may include falling trees, storms, rain and snow, winds, etc. An additional consequence of unwanted discharge and sparks etc. is unwanted noise which is passed along the electric wires, and which disturbs any communications traffic. Furthermore, unwanted discharge may cause sparks or other discharge that may lead to wasted energy.

Discharges need to be identified and fixed, preferably well before the insulators and other network equipment cease to work all together. It would be advantageous to have a system, apparatus or method for remotely identifying discharge in an electric circuit.

### SUMMARY OF THE INVENTION

An object of the present embodiments is to improve efficiency of remote detection of discharges. A further object is to provide an estimate of the location of the discharge.

The present embodiments use high pass filtering at a communications modern to remotely identify the impulse type noises characteristic of an electrical discharge. Detected discharge is then reported over the communications system.

According to an aspect of some embodiments of the present invention there is provided apparatus for remote detection of discharge on a power line, comprising:

a high pass filter for filtering high frequency components of a signal on a power line, the high frequency components being indicative of discharge within the signal;

a comparator unit, for comparing the frequency of the signal to a threshold signal; and

a controller unit for identifying a likely discharge event, based on the signal.

An embodiment may comprise a reporting unit, to report the likely discharge event to a network management unit.

An embodiment may comprise a network management unit to process received data, and identifying the likely source of the likely discharge event.

In an embodiment, the power line has a line frequency, the apparatus further comprising a phase unit for determining whether the identified components are in phase with the line frequency.

In an embodiment, the power line has a line waveform, the waveform including peaks and troughs, the apparatus further comprising a comparison unit for determining whether the identified components substantially coincide with the peaks and troughs.

An embodiment may comprise a thresholder configured to threshold the signals against a predetermined amplitude.

An embodiment may comprise an amplitude measuring unit for measuring an amplitude from the detected components.

Embodiments may be being incorporated within a power line communication unit.

According to a second aspect of the present invention there is provided a power line network comprising:

a plurality of power line communication units distributed over the network; and

a network management unit;

at least some of the communication units respectively comprising a high pass filter configured for detection of high frequency pulses indicative of remote discharges, and a reporting unit for reporting the detection to the network management unit.

In an embodiment, the reporting unit is configured to report an amplitude associated with the high frequency pulses.

In an embodiment, the network management unit is configured to use respective reported amplitudes together with a location in the network of respective reporting communication units to estimate a location of a discharge.

According to a third aspect of the present invention there is provided a method for remote detection of discharge events on a power line network the power line network having a line frequency, comprising:

sampling the network at a first location;

extracting high frequency components indicative of the presence of impulse-type noise;

testing the high frequency components for regularity against the line frequency; and

whenever high frequency components are extracted and indicate the regularity, reporting a detection of a discharge event.

In an embodiment, the extracting comprises using a high pass filter.

An embodiment may comprise thresholding the extracted components to exclude noise.

An embodiment may comprise detecting an amplitude of the extracted components.

An embodiment may comprise carrying out further sampling, extracting, testing and reporting from a second location.

An embodiment may comprise receiving the reports and superimposing the locations onto a map to determine if the reports cluster.

In an embodiment, if the reports cluster, then one may weight each reporting location with an amplitude of the reported discharge event to find a center of the cluster, and providing the center as an estimate for a discharge location.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks to could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a simplified diagram showing discharge noise on an AC waveform;

FIG. 2 is a simplified diagram showing a device for detecting or measuring discharge events remotely, according to a first embodiment of the present invention;

FIG. 3 is a simplified diagram showing a network management system providing an estimate of the location of a discharge according to an embodiment of the present invention;

FIG. 4 is a simplified flow chart showing an example of operation of a device for remotely detecting discharge events; and

FIG. 5 is a simplified flow chart showing exemplary operation of a network management device for estimating the location of a discharge.

### DESCRIPTION OF EMBODIMENTS OF THE INVENTION

The present invention, in some embodiments thereof, relates to remote detection of discharge on a power line network and, more particularly, but not exclusively, to such remote detection by units of a communication system installed on the power line network. The units use high pass filtering to identify impulse-type behaviour within the line noise. Impulse-type behaviour is a sign of electrical discharge. Hereinafter, components of line noise that exhibit impulse-like behaviour will be referred to inter alia as impulses.

Discharges tend to occur when the voltage is highest/lowest so if the detected impulses have a period which corresponds with the line frequency then this is a further sign of discharge.

A level trigger may then be used to filter out insignificantly small impulses. The trigger may be set dynamically at a level that filters out impulses that do not correspond with the line period.

If a set of impulses are detected that are regular in nature, and are very high frequency or impulse like, and also above a certain threshold in amplitude, then these are a good indication of discharge in the neighborhood, possibly due to a failing insulator.

The resulting impulses may then be reported to a central controller. The same impulses may be detected by several communication units and the height of the impulse may indicate the distance from the discharge source. The central controller, knowing the locations of the various communications units, can make an estimate as to the location of the discharge so that a line man, electrician or technician can be sent as early as possible to repair the fault, replace the insulator etc.

Before explaining at least one embodiment of the invention in detail, it is to be understood that the invention is not necessarily limited in its application to the details of construction and the arrangement of the components and/or methods set forth in the following description and/or illustrated in the drawings. The invention is capable of other embodiments or of being practiced or carried out in various ways.

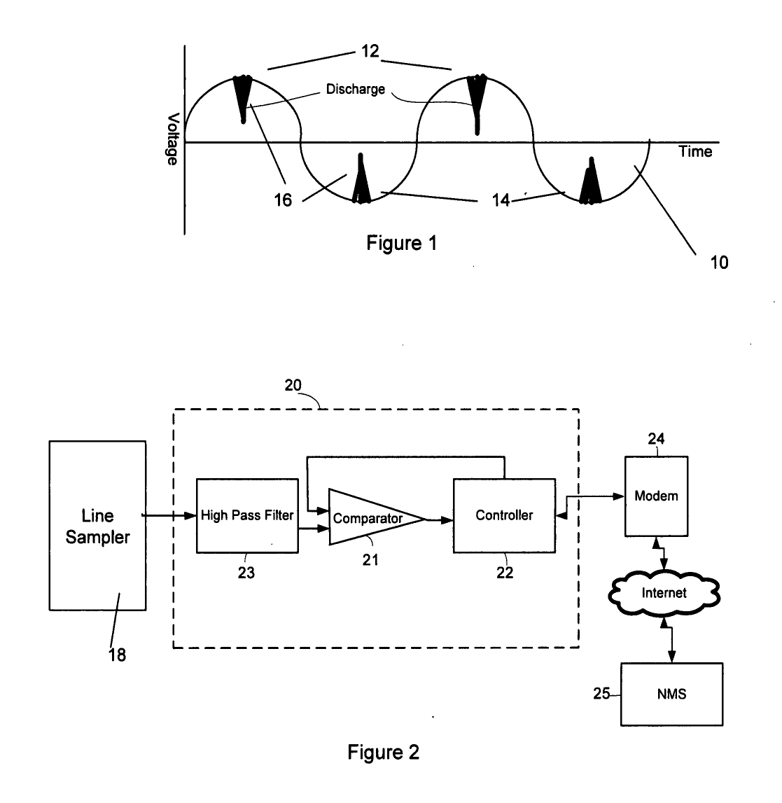

Referring now to the drawings, FIG. 1 illustrates a typical line voltage of a power line in which discharge is occurring over time. A standard AC waveform 10 includes maxima or peaks 12 and minima or troughs 14, wherein the modulus of the voltage is at a maximum with respect to ground. At these peaks and troughs, any weakness in any paths to ground may cause electrical breakdown and lead to discharge. Discharge events 16 if present may show up as a single pulse or a series or cluster of narrow impulse-like pulses around the peaks and troughs. The magnitudes of the impulse-like pulses tend to increase towards the voltage peak, as shown in the figure.

Reference is now made to FIG. 2, which is a schematic diagram showing line sampling unit 18, which is part of communications equipment for a communication network over the power line, for example, a coupler. In some embodiments there may be no line sampling unit, for example, when apparatus 20 is connected underground, to low voltage lines etc. Attached to line sampling unit 18 is apparatus 20 for remote detection and/or measuring of discharge on a power line. The apparatus 20 obtains samples of a signal on a power line from the sampler 18 and passes the samples to high pass filter 23, which may be a capacitor. The high pass filter, for example, may filter out regular electric current or low frequency signals, and allows high frequency signals to be transmitted to comparator 21. In this way, high pass filter 23 filters through high frequency pulses only, which are indicative of discharge in a signal, and following processing, any indication of a discharge.

Charges passing through high pass filter 23 are transferred via comparator 21 to controller 22. Controller 22 may be configured to transmit commands or codes to comparator 21, to cause comparator 21 to run comparisons between received transmission signals and pre-configured threshold requirements. These comparisons are able to determine whether signals received may be considered discharges. Comparator 21 may be used as a thresholder to threshold the pulses against a predetermined amplitude. The threshold may be set in advance at a level found to exclude most irrelevant noise but not to exclude those pulses indicating discharge events. The threshold may be set or corrected dynamically to exclude irregular pulses. That is to say the irregular pulses are identified as noise, so by setting the threshold to a level that excludes the irregular pulses, current levels of noise are catered for.

Controller 22 may receive data from comparator 21 relating to the discharge data, and may determine, based on the discharge data, whether there has been a discharge event. In some embodiments controller 22 may require multiple samples of discharge data at selected intervals, to determine that a likely discharge event is occurring. For example, if the controller receives discharge data at a selected threshold frequency of 50 Hz every 10 or 20 milliseconds, or 8.3 or 16.6 milliseconds for 60 Hz, this may be considered a high likelihood of a discharge event. In such a case, an event alert or message may be forwarded to a reporting unit, part of controller 22, for reporting identified pulses as a likely remote discharge. Reporting is made via modem 24 to a network management system NMS 25. Further, controller may be able to identify the element, component or area from where the highest frequency signal emanates. This data may be forwarded to the NMS 25, to aid NMS in identifying the location of the likely discharge.

NMS 25 may process received discharge data, for example, by plotting likely discharge sources on a location map, thereby graphically identifying the location(s) of likely discharge. NMS 25 may run one or more codes or algorithms on the received data to determine its regularity, strength, location, etc. In some embodiments NMS 25 may compile a report or alert informing the network system or the network operators of one or more discharge sources, and/or the positions or locations of these sources etc.

As explained, the power line has a line frequency, and the combination of comparator 21 and controller 22 is able to provide a phase unit for determining whether the identified impulses are in phase with the line frequency. If the pulses output by the high pass filter are regular and correspond to the peaks and troughs in the AC waveform of the line frequency then they may be identified as belonging to a discharge event. If the pulses are irregular, or do not correspond with the peaks and troughs then they are unlikely to correspond to discharge events.

In an alternative example, an event may be detected and measured as follows: A line sample may be filtered by high pass filter 23, and thereafter entered into a comparator 21. A controller 22, that is associated with comparator 21, may accumulate high band pulses over a period say of a second. The controller may then note how many of these high band pulses have been accumulated, the time between pulses etc. If the pulses correspond to the peaks and troughs of the line they may be identified as discharge noise.

Once noise has been identified, the settings of comparator 21 may be adjusted, for example, to determine the precise size of the pulse or discharge, for example, to determine what threshold level just stops the pulses. That is to say, according to some embodiments, settings of comparator 21 are dynamically adjusted, to set the threshold level to just exceed that of the pulses. The threshold level making the pulses disappear is then taken as the discharge event amplitude and included in the event report.

The apparatus 20 may be incorporated within a power line communication unit, for example a repeater. The communication unit may be part of a system for maintaining the power line network and/or it may be part of a communication network that uses the power line network as an infrastructure for telephony or Internet communications and the like.

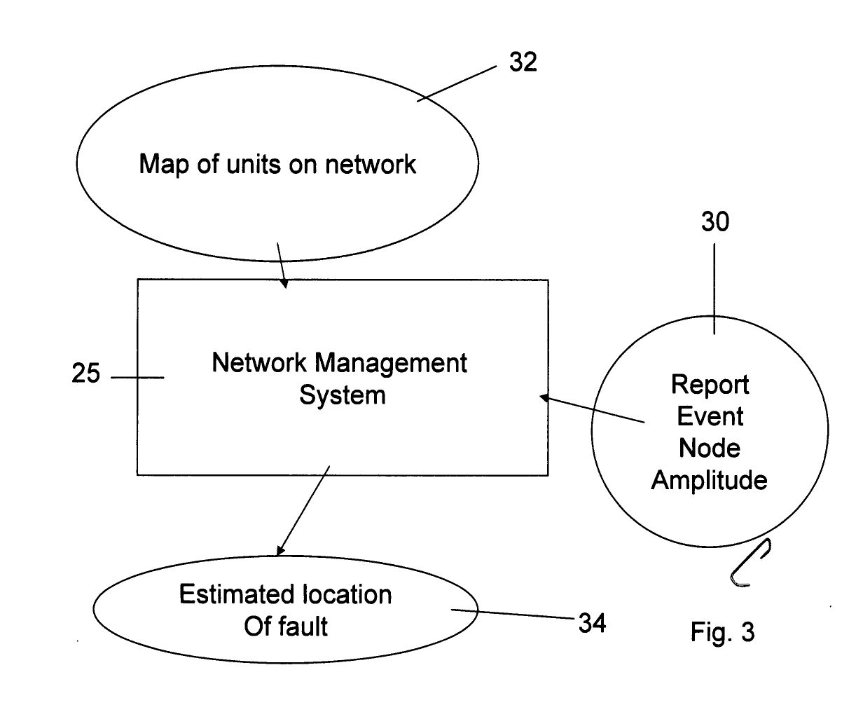

Reference is now made to FIG. 3, which is a simplified diagram illustrating the network management system 25 and showing how it can be used to estimate the location of a discharge on the network.

Various communication units on the network send in reports 30 regarding discharge events. Each report may include the identity of the reporting unit and an amplitude of the detected discharge event. It will be appreciated that the closer a unit is to the source of a discharge the greater the amplitude will be, so that if the same event is received from several units then the reporting units can be ranked in order of proximity to the event. The network management system includes a map 32 of units on the physical network so that the ranking can be used to pinpoint an area on the network where the discharge comes from. The pinpointed area is output as an estimate 34 of the location of the fault and a lineman or technician can be dispatched to deal with the situation before it becomes any more serious.

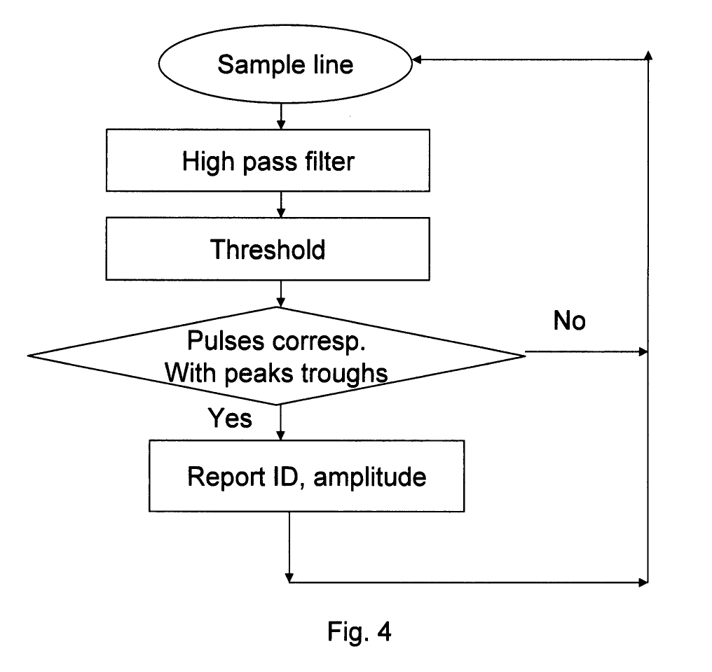

Reference is now made to FIG. 4 which is a simplified flow chart illustrating a method of remotely detecting and also measuring a discharge event from a communication unit. The power line is sampled. Sampling is typically continuous as this is needed for the basic communication function of the unit. The results are passed through a high pass filter to isolate only those components of the line noise having impulse like characteristics. The output of the high pass filter is then thresholded to filter out irrelevant noise and the result is tested for compatibility with the peaks and troughs or maxima and minima of the line frequency. If the test result is positive then a report is sent giving the unit ID and an amplitude. If the test is negative then no report is made. In either event sampling continues.

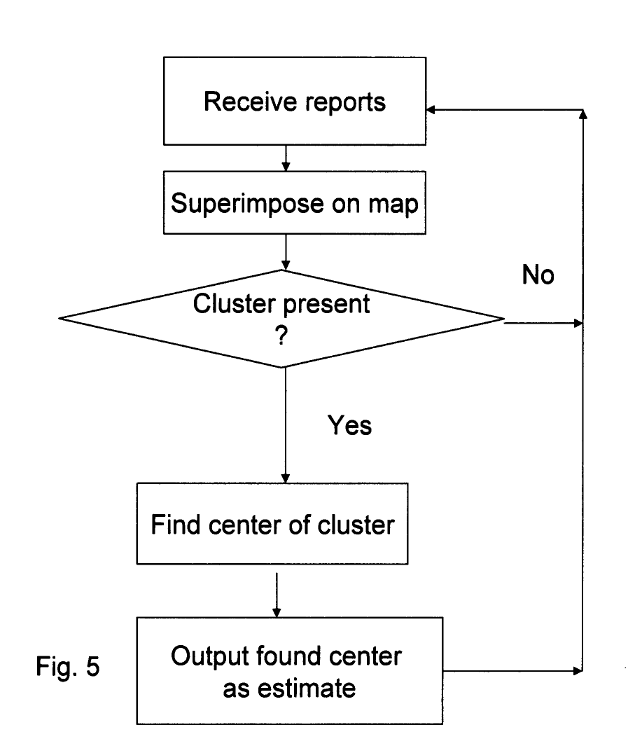

Reference is now made to FIG. 5, which illustrates an exemplary procedure at the network management system 25. Reports are received from the various communication units and the reporting units are superimposed on a physical map of the network. The system looks for clustering on the map, as clustering indicates that one or more units are reporting the same discharge event. Clustering, as used herein, refers to the identifying of a source location or area where the highest amplitude of signals indicative of discharge is found. In some embodiments clustering may include one or more signals or sources. For example, if a cluster is found then the center of the cluster is identified. A number of algorithms are possible for obtaining the center of the cluster and a typical algorithm involves weighting each reporting unit with a value based on the reported amplitude. Then a location is searched for which represents a center of gravity with respect to the weightings. The location is then output as the reported estimate for the fault location.

The source of a discharge is often a faulty insulator. Power lines include numerous insulators which are liable to break, get dirty, perish over time, loose functionality etc., in which case electrical breakdown may occur over the insulator, for example, causing unwanted sparks. An additional consequence of unwanted discharge and sparks etc. is unwanted noise which is passed along the electric wires and can upset communications apparatus. Furthermore, damaged lines, for example caused by falling trees, vegetation, damaged equipment, damaged cables or installations, fallen poles, faulty transmitters etc., may cause sparks or other discharge that may lead to wasted energy.

As explained with reference to FIG. 1, discharge may generally occur at high or low voltage peaks. Such discharges may cause noise, which is hereinafter referred to as Gap noise.

As explained, by detecting and measuring the gap noise over time, discharge events may be detected and even located. Detection uses high pass filtering followed by amplitude measurement and a decision on the regularity of the detected noise. In addition to the high pass filter, detection may involve A/D conversion and then digital processing to measure the amplitude and detect timing patterns. Alternatively, analogue equipment may be used to achieve the same.

The above procedure may be used to determine the existence of discharge, and processing may be used to determine the quantity or quality of discharge over time or other selected parameters. In some embodiments, knowledge of the existence, quality and quantity of discharge may help a grid management system achieve more effective energy planning, scalability and usage efficiency. For example, a utility may use such data, including historical data, statistical data, analytics etc., to plan infrastructure development according to energy usage history, to remove and/or prevent safety hazards, and to operate in a more environmental-friendly way. In some embodiments such noise identification may be used to analyze system, network or grid diagnostics, which may help to determine sources of discharge, patterns of efficiency and inefficiency and more.

In one embodiment a unit is placed in association with a transformer. The unit detects gap noise from within the transformer and uses this as an indication that the transformer requires servicing before it fails. That is to say gap noise is an early indication of transformer failure.

In addition, if the communication unit is placed inside the transformer, then sensors can be added to measure for other indicators of potential failure, such as temperature, water or insulating oil levels etc. Upon reporting a potential failure the communication unit may be used via its outputs to operate switches and for example carry out automatic maintenance or failsafe procedures on the transformer.

The terms “comprises”, “comprising”, “includes”, “including”, “having” and their conjugates mean “including but not limited to”.

As used herein, the singular form “a”, “an” and “the” include plural references unless the context clearly dictates otherwise.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. Apparatus for remote detection of discharge on a power line, comprising:
a high pass filter for filtering high frequency components of a signal on a power line, said high frequency components being indicative of discharge within said signal;
a comparator unit, for comparing the frequency of said signal to a threshold signal; and
a controller unit for identifying a likely discharge event, based on said signal.

2. The apparatus of claim 1, comprising a reporting unit, to report said likely discharge event to a network management unit.

3. The apparatus of claim 2, comprising a network management unit to process received data, and identifying the likely source of said likely discharge event.

4. The apparatus of claim 1, wherein the power line has a line frequency, the apparatus further comprising a phase unit for determining whether said identified components are in phase with said line frequency.

5. The apparatus of claim 1, wherein the power line has a line waveform, the waveform including peaks and troughs, the apparatus further comprising a comparison unit for determining whether said identified components substantially coincide with said peaks and troughs.

6. The apparatus of claim 1, further comprising a thresholder configured to threshold said signals against a predetermined amplitude.

7. The apparatus of claim 1, further comprising an amplitude measuring unit for measuring an amplitude from said detected components.

8. The apparatus of claim 1, being incorporated within a power line communication unit.

9. A power line network comprising:
a plurality of power line communication units distributed over said network; and
a network management unit;
at least some of said communication units respectively comprising a high pass filter configured for detection of high frequency pulses indicative of remote discharges, and a reporting unit for reporting said detection to said network management unit.

10. The power line network of claim 9, wherein said reporting unit is configured to report an amplitude associated with said high frequency pulses.

11. The power line network of claim 10, wherein said network management unit is configured to use respective reported amplitudes together with a location in said network of respective reporting communication units to estimate a location of a discharge.

12. A method for remote detection of discharge events on a power line network the power line network having a line frequency, comprising:
sampling said network at a first location;
extracting high frequency components indicative of the presence of impulse-type noise;
testing said high frequency components for regularity against the line frequency; and
whenever high frequency components are extracted and indicate said regularity, reporting a detection of a discharge event.

13. The method of claim 12, wherein said extracting comprises using a high pass filter.

14. The method of claim 12, further comprising thresholding said extracted components to exclude noise.

15. The method of claim 12, further comprising detecting an amplitude of said extracted components.

16. The method of claim 12 comprising carrying out further sampling, extracting, testing and reporting from a second location.

17. The method of claim 16, further comprising receiving said reports and superimposing said locations onto a map to determine if said reports cluster.

18. The method of claim 17, wherein, if said reports cluster, then weighting each reporting location with an amplitude of said reported discharge event to find a center of said cluster, and providing said center as an estimate for a discharge location.
